(19) United States
(12) Patent Application Publication
(10) Pub. No.: US 2008/0157162 A1
(43) Pub. Date: Jul. 3, 2008

(54) Method of combining floating body cell and logic transistors

(76) Inventors: Brian S. Doyle, Portland, OR (US); Suman Datta, Beaverton, OR (US); Jack Kavalieros, Portland, OR (US); Robert Chau, Beaverton, OR (US)

Correspondence Address: INTEL/BLAKELY, 1279 OAKMEAD PARKWAY, SUNNYVALE, CA, 94085-4040, US

(21) Appl. No.: 11/646,757

(22) Filed: Dec. 27, 2006

(51) Int. Cl. H01L 21/336; H01L 29/788

(52) U.S. Cl. 257/315; 438/257; 257/E21.422; 257/E29.3

(57) ABSTRACT

An integrated circuit having both floating body cells and logic devices fabricated in a bulk silicon substrate is described. The floating body cells have electrically floating bodies formed by oxidizing a lower portion of the cell bodies to electrically isolate them from the substrate.

### FIELD OF THE INVENTION

The invention relates to the field of fabricating floating body memory cells and logic devices on a common substrate, and the resultant integrated circuit.

### PRIOR ART AND RELATED ART

Most common dynamic random-access memory (DRAM) cells store charge on a capacitor and use a single transistor for accessing the capacitor. More recently, a cell has been proposed which stores charge in a floating body of a transistor. A back gate is biased to retain charge in the floating body. A front gate is used to sense the presence or absence of charge by determining the voltage threshold and to write data into the cell.

In one proposal, an oxide layer is formed on a silicon substrate and a silicon layer for the active devices is formed on the oxide layer (SOI substrate). The floating bodies are defined from the silicon layer; the substrate is used as a back or biased gate. One problem with this arrangement is the relatively high voltage required on the back gate because of the thick oxide. If the oxide is made thin, other problems arise in using the thin oxide for the logic circuits. In a related application, an SOI layer is used for the floating body devices; in other regions of the substrate the SOI layer is removed, allowing logic devices to be fabricated in the underlying bulk substrate. This is described in co-pending application Ser. No. ______, filed ______, entitled “Integration of a Floating Body Memory on SOI with Logic Transistors on Bulk Substrate.”

Several structures have been proposed to reduce the relatively high bias potential discussed above, including use of a double gate floating body and silicon pillars. These structures are difficult to fabricate. This and other related technology is described at C. Kuo, IEDM, December 2002, following M. Chan Electron Device Letters, January 1994; C. Kuo, IEDM, December 2002, “A Hypothetical Construction of the Double Gate Floating Body Cell;” T Ohsawa, et al., IEEE Journal of Solid-State Circuits, Vol. 37, No. 11, November 2002; and David M. Fried, et al., “Improved Independent Gate N type FinFET Fabrication and Characterization,” IEEE Electron Device Letters, Vol. 24, No. 9, September 2003; Highly Scalable FBC with 25 nm BOX Structure for Embedded DRAM Applications, T. Shino, IDEM 2004, pgs 265-268; T Shino, IEDM 2004, “Fully-Depleted FBC (Floating Body Cell) with enlarged signal Window and excellent Logic Process Compatibility;” T Tanaka, IEDM 2004, “Scalability Study on a Capacitorless lT-DRAM: From Single-gate PD-SOI to Double-gate FinDRAM; U.S. Patent Application 2005/0224878; and “Independently Controlled, Double Gate Nanowire Memory Cell with Self-Aligned Contacts,” U.S. patent application Ser. No. 11/321,147, filed Dec. 28, 2005.

Another floating body memory formed on a bulk substrate is described in Symposium on VLSI Technology Digest of Technical Papers, page 38, 2005 by R. Ranica, et al. The floating p well, as described, is isolated from neighboring devices by a shallow trench isolation region and underlying n well.

A technique for using a silicon germanium (SiGe) layer to form a floating body is described in “Gate-Assisted SOI on Bulk Wafer and its Application to Floating Body Memory,” U.S. patent application Ser. No. ______, filed ______.

### DESCRIPTION OF THE DRAWINGS

FIG. 1 is a cross-sectional, elevation view of a substrate having defined thereon a first body and a second body.

FIG. 2 illustrates the structure of FIG. 1, following the formation of trench oxide.

FIG. 3 illustrates the structure of FIG. 2, after the trench oxide is etched back.

FIG. 4 illustrate the structure of FIG. 3, following the deposition of a nitride layer.

FIG. 5 illustrates the structure of FIG. 4, following the formation of a protective layer, to protect the logic devices.

FIG. 6 illustrates the structure of FIG. 5, following the formation of spacers on the upper region of the first body.

FIG. 7 illustrates the structure of FIG. 6, following recessing of the first body.

FIG. 8 illustrates the structure of FIG. 7, following an etching step used to expose a portion of the first body underlying the spacers.

FIG. 9 illustrates the structure of FIG. 8, following an oxidation used to oxidize regions of the first body.

FIG. 10 illustrates the structure of FIG. 9, following removal of the protective layer and nitride layer.

FIG. 11 illustrates the structure of FIG. 10, during the formation of a gate dielectric and gates.

FIG. 12 illustrates the structure of FIG. 11, following a polishing step.

FIG. 13 illustrates the structure of FIG. 12, following formation of gates for the floating body memory cell and logic device.

### DETAILED DESCRIPTION

In the following description, memory devices, more specifically floating body memory cells (FBCs), and a method for fabricating the cells on a bulk substrate which includes logic devices, is described. Numerous specific details are set forth to provide a thorough understanding of the present invention. It will be apparent to one skilled in the art, that the present invention may be practiced without these specific details. In other instances, well-known processing steps such as cleaning and etching steps, are not described in detail to avoid unnecessarily obscuring the present invention.

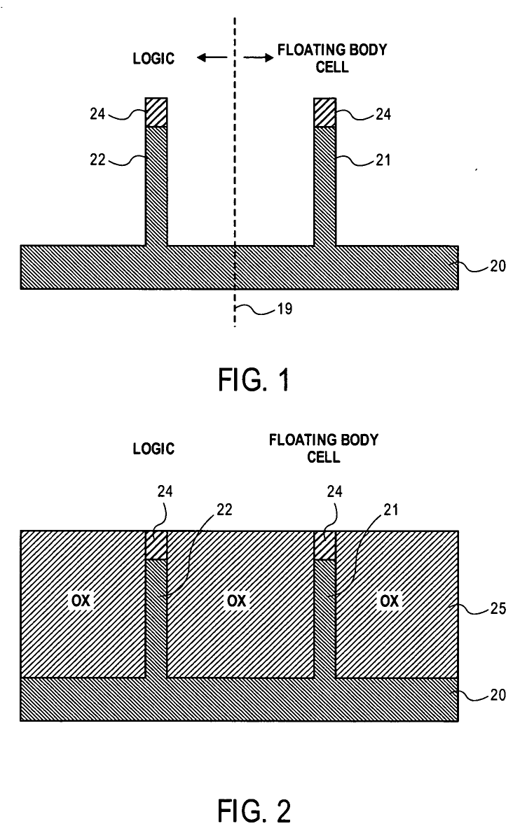

Referring to FIG. 1, a monocrystalline silicon substrate 20 is illustrated in a cross-sectional, elevation view after the fins or bodies 21 and 22 have been etched from the substrate. The etching process typically includes the formation of a pad oxide, not illustrated, and the formation of a silicon nitride layer. The nitride layer is patterned to form the masking members 24, allowing the bodies 21 and 22 to be etched from the substrate 20 in alignment with the masking members.

A dotted line 19 is illustrated in FIG. 1. To the right of the line 19, the processing for floating body cells is illustrated in the subsequent figures. To the left of the line 19, the processing for the bodies, used for logic transistors, is described. Typically, a plurality of parallel, spaced-apart bodies 21 are fabricated so that a memory array of FBCs can be formed. In other regions of the substrate, logic devices (e.g. n-channel or p-channel transistors) are fabricated from the body 22, and like bodies. While a single body 22 is shown in FIG. 1, it will be appreciated that many such bodies are simultaneously fabricated, some of which become n channel transistors and others which become p channel transistors.

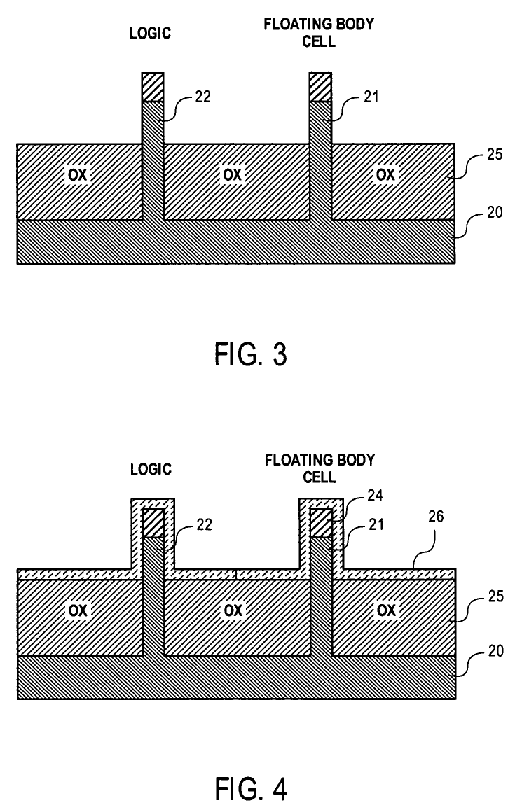

In the following description, the logic transistors are described as tri-gate transistors with narrow channels (i.e. fully depleted) devices. Planar transistors can also be fabricated with the described process; however, to do so the etching step described in conjunction with FIG. 3, must be modified. During the etching discussed in conjunction with FIG. 3, the logic devices are protected thereby leaving the sides of the bodies protected in the subsequent processing.

Referring now to FIG. 2, after the bodies 21 and 22 are formed, a shallow trench isolation oxide 25 is deposited and polished to form the structure of FIG. 2. Note that in FIG. 2 and the subsequent figures, the dotted line 19 has not been drawn again.

Then, as shown in FIG. 3, the trench oxide 25 is etched back with a dry or wet etchant to a level such that the upper portion of the bodies 21 and 22 extend above the upper surface of the oxide 25. The exposed height of the bodies is the height necessary for the device. For an example, where the bodies have a width of 25 nm, the exposed height may also be 25 nm.

Next, as shown in FIG. 4, a silicon nitride layer 26 is deposited over the substrate. In one embodiment, this is an isolation nitride (ISON) layer, more specifically, a high quality silicon nitride (i.e. close to perfect Si₃N₄ stoichiometry) that, for instance, is deposited by chemical vapor deposition (CVD) at a relatively high temperature (e.g. approximately 700° C. or higher).

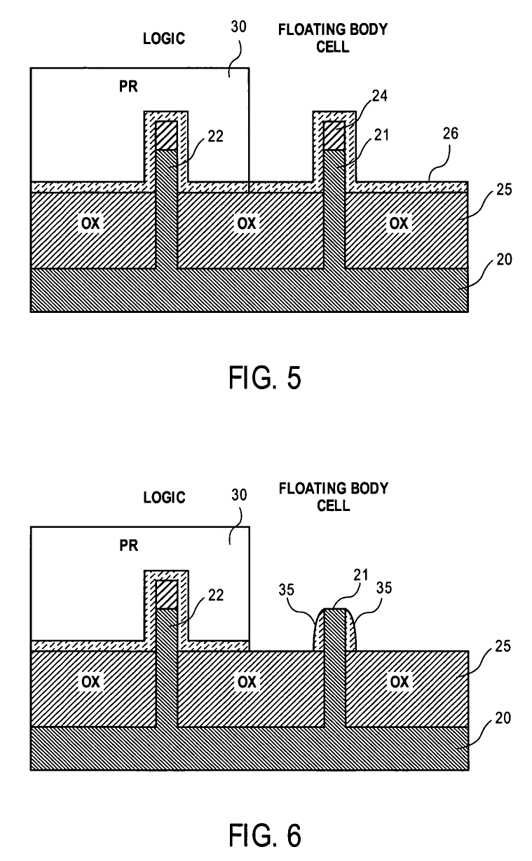

As illustrated in FIG. 5, a relatively thick protective layer, such as the photoresist layer 30, is deposited and patterned to protect the bodies for the logic devices such as the body 22. This is done to allow separate processing for the FBCs.

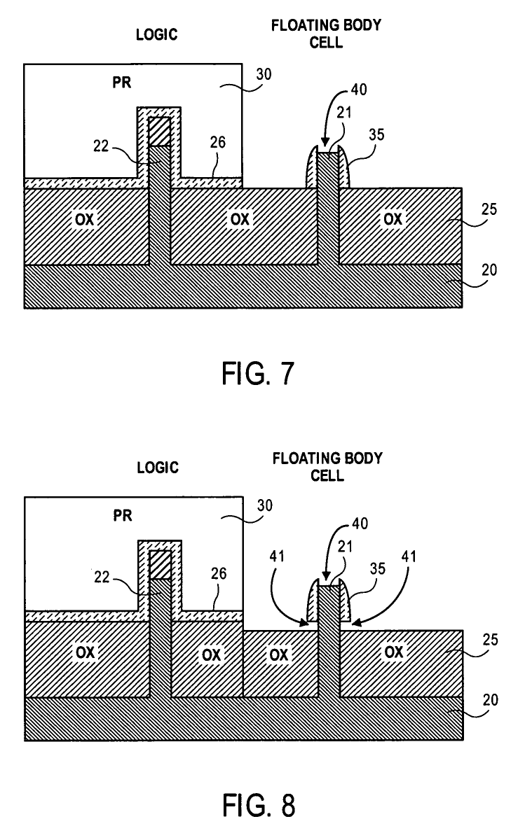

An anisotropic (dry) etching step is used to etch the ISON layer. This processing forms spacers 35 on the sides of the body 21, as shown in FIG. 6. Then, an optional silicon etching step is used to recess the body 21 within the spacers as shown by recess 40 of FIG. 7. This recessing may be used to allow the formation of silicon dioxide in subsequent processing within the recess 40. The oxide assures isolation between the front and back gates for the FBCs.

Another oxide etching step is used to etch back the oxide 25 where it is exposed. This etching step need only remove a relatively small amount of oxide 25 to create the recesses 41 of FIG. 8. These recesses expose the underside of the spacers 35 and importantly, leave exposed a lower portion of the body 21.

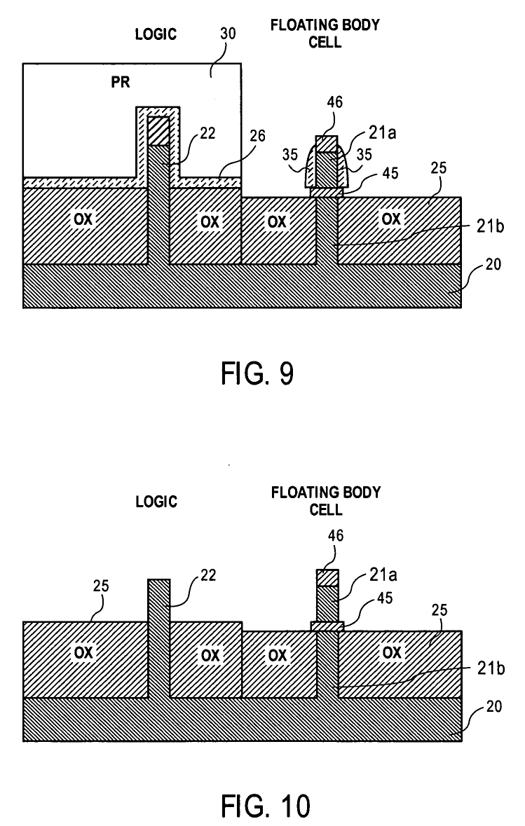

Now, an ordinary oxidation step is used to oxidize the silicon. The only exposed silicon in FIG. 8 is within the recesses 40 and 41. The oxidation results in the formation of the oxide region 45 disposed between the bottom of the spacers 35 and the upper surface of the oxide 25, as shown in FIG. 9. Additionally, oxide region 46 forms on the upper surface of the body 21 as shown in FIG. 9. It should be noted from FIG. 9, that the body 21 shown in the previous figures now comprises a body 21a separated from a body 21b by the oxide region 45. Consequently, the body 21a is electrically isolated from the body 21b and substrate 20. Thus, the FBCs are fabricated with truly electrically floating bodies.

At this point in the processing, the photoresist layer 30 and underlying ISON layer 26, along with the spacers 35 are removed. Ordinary etchants may be used for this purpose and, for instance, a hot phosphoric acid may be used to remove the layer 26. The resultant structure is shown in FIG. 10. Note that the floating body 21a remains isolated from the underlying body 21a, and moreover, the oxide region 46 remains on the upper surface of the body 21a.

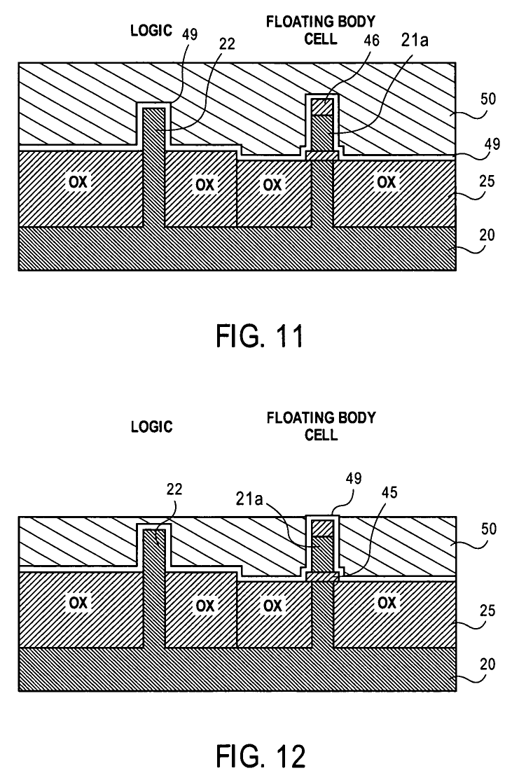

Ordinary processing is now used to form the gate structures and the source and drain regions. As shown in FIG. 11, a gate insulator 49 is deposited. For instance, a high k dielectric such as HfO₂ may be deposited. Following this, metal gate layers may be formed. For example, a metal favoring p channel devices may be formed on the bodies which will be used for p channel transistors, and a metal favoring n channel devices may be formed on the bodies for the n channel transistors. Alternatively, polysilicon may be used for the gate material. Moreover, polysilicon may be deposited over the metal gates to provide a conductive path to the metal. A polysilicon layer 50 is shown in FIG. 11, separated from the bodies by the dielectric layer 49.

In FIG. 12, the resultant structure is shown following the polishing of the polysilicon 50. While not illustrated, a replacement gate process may be used to form the gate structures. Moreover, not illustrated are known steps for forming the source and drain regions for both the FBCs and logic devices, including the formation of additional spacers for the tip and main parts of the source and drain regions.

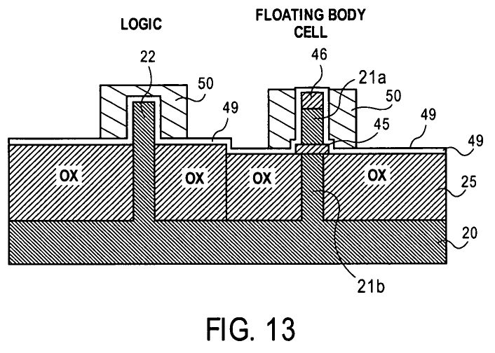

Completed devices are shown in cross-sectional view in FIG. 13 with the polysilicon portion of the gates 50 shown. The logic devices have a tri-gate structure, whereas the FBCs have two separate gate structures, one for a back gate and one for a front gate. Note the oxide 46 assures that the gates remain well separated from one another since they are differently biased in operation. The oxide region 45 likewise remains in place assuring that the floating bodies 21a for the cells remain electrically isolated from the substrate.

Thus, a method for fabricating a memory and the memory has been described where floating body cells are fabricated along with logic devices on a bulk semiconductor substrate.

What is claimed is:

1. A method comprising:
forming a plurality of bodies from a bulk silicon substrate;
forming spacers on opposite sides of the bodies such that the bottom of the spacers are spaced apart from the substrate; and
oxidizing the bodies at regions where the spacers are spaced apart from the substrate.

2. The method of claim 1, including the following before forming the spacers:
depositing an oxide between the bodies; and
etching the oxide back so as to leave a portion of the bodies exposed.

3. The method of claim 2, wherein forming the spacers includes:
depositing a layer of silicon nitride; and
anisotropically etching the layer of silicon nitride.

4. The method of claim 3, wherein after forming the spacers, the following occurs:
etching back the oxide again with a wet etchant to expose the bodies below the spacers.

5. The method of claim 4, wherein the region of the oxidation of the bodies is between the bottom of the spacers and a top of the etched back oxide.

6. The method of claim 5, including:
forming second bodies simultaneously with the bodies formed in claim 1; and
protecting the second bodies during the forming of the spacers such that spacers are not formed on the second bodies when the spacers of claim 1 are formed;
wherein the second fins are used for logic devices.

7. The method defined by claim 1, wherein forming the spacers include depositing a silicon nitride layer.

8. The method of claim 7, wherein the region of the oxidation of the bodies is between the bottom of the spacers and a top of an etched back oxide.

9. The method of claim 8, including:
forming a trench oxide between the bodies; and
wet etching the trench oxide so as to expose the body under the spacers to permit the oxidation.

10. The method defined by claim 1, wherein the bulk semiconductor substrate is a silicon substrate.

11. The method defined by claim 1, including forming a trench oxide between the bodies before the formation of the spacers.

12. The method defined by claim 1, including simultaneously forming other bodies with the bodies of claim 1, without forming spacers on the other bodies.

13. A method comprising:
forming first and second bodies from a bulk silicon substrate;
forming spacers on opposite sides of the first bodies such that the bottom of the spacers are spaced apart from the substrate; and
oxidizing the first bodies in a region where the spacers are spaced apart from the substrate so as to cause the first bodies to be electrically insulated from the substrate.

14. The method of claim 13, including:
following the formation of the bodies and before forming the spacers, depositing a trench oxide layer between the first and second bodies; and
etching back the trench oxide layer such that an upper portion of the bodies is exposed.

15. The method of claim 14, wherein the region of oxidation of the first bodies is disposed between the bottom of the spacers and the top of the trench oxide layer.

16. The method of claim 15, including:
forming first and second gates on opposite sides of the first bodies so as to form floating body memory cells; and
forming third gates disposed about the second bodies so as to form logic devices.

17. The method of claim 16, wherein the first, second and third gates are insulated from their respective bodies by a high k insulation, and wherein the gates comprise metal.

18. An integrated circuit comprising:
a plurality of first bodies each extending from a silicon substrate and having a first upper region defining a floating silicon body insulated from a second region of the body by a silicon dioxide region;
trench isolation oxide disposed between the first bodies to a level approximately equal to a lower extent of the silicon dioxide regions;
second bodies extending continuously upward from the substrate to a level approximately equal to the upper level of the first bodies;
first and second gates disposed on opposite sides of the first bodies, defining floating body memory cells; and
third gate structures disposed on opposite sides and top of the second bodies defining logic devices.

19. The integrated circuit defined by claim 18, wherein a high k dielectric separates the first, second and third gates from their respective bodies.

20. The integrated circuit defined by claim 19, wherein the first, second and third gates comprise metal.
